(19) United States
(12) Patent Application Publication
(10) Pub. No.: US 2004/0107904 A1
(43) Pub. Date: Jun. 10, 2004

(54) Vacuum vaporization unit for the metal coating of a strip substrate and corresponding vaporization source

(76) Inventors: Fabiano Rimediotti, Prato (IT); Mario Ceni, Firenze (IT); Andrea Fusi, Firenze (IT)

Correspondence Address: John James McGlew, McGLEW AND TUTTLE, Scarborough Station, Scarborough, NY, 10510-0827, US

(21) Appl. No.: 10/680,502

(22) Filed: Oct. 7, 2003

Related U.S. Application Data
(63) Continuation-in-part of application No. PCT/IT02/00411, filed on Jun. 21, 2002.

(30) Foreign Application Priority Data
Oct. 8, 2002 (EP) EP 02 425 603

(51) Int. Cl. C23C 16/00

(52) U.S. Cl. 118/718; 118/723 VE

(57) ABSTRACT

The equipment comprises: a plurality of vaporization sources (31) which are heated and fed with a metal which is liquefied and vaporized by said sources; and means for feeding the substrate (N) above the sources. Each source has two cavities (41A, 41B) which are aligned along the direction in which the substrate is fed, and each of said two cavities is fed by a corresponding metal wire delivered by corresponding delivery means (51, 53).

### TECHNICAL FIELD

This invention relates to equipment for the metal coating of a strip substrate, for example a film of plastic material on which a metal coating or the like has to be formed, by vacuum vaporization. More particularly, the invention relates to vacuum vaporization equipment for the metal coating of a strip substrate of the type comprising:

a plurality of vaporization sources heated and fed with a metal which is liquefied and vaporized by said sources,

means for feeding said substrate over said sources, in the direction of feed, said source having an elongated body in the direction of feed,

means for delivering metal wire to said sources.

The invention also relates to a vaporization source which can be used in an equipment of the aforesaid type.

### STATE OF THE ART

Equipment for metal coating by vaporization in which a film or other substrate is unwound from a delivery spool, passed around a process roller and again wound onto a treated material spool are known for the vacuum metal coating of plastic films or other continuous strip substrates. In the zone in which the substrate is passed around the process roller it passes a number of vaporization sources which are located—together with at least part of the process roller—in a vacuum chamber in which a cloud of vaporized metal material from the source is formed. This metal material is deposited on the substrate by condensation, and the latter is then rewound onto the spool for treated material.

The process is a process of the batch type, in which individual spools of substrate requiring treatment are placed in the equipment, the equipment is sealed and placed under vacuum, the substrate is treated, and subsequently the spool of treated and wound substrate is removed from the equipment to be replaced by another spool of substrate requiring treatment.

A description of the nature of the problems with such equipment can be found in G. Tonini, F. Grazzini, N. Merlini, “A New Generation of Film Metallizing” in Paper, Film and Foil Converter”, February 1980.

The vaporization sources may have different configurations. These include vaporization sources of electrically conducting material which are heated by the direct passage of current. In this case the source is constructed in the form of a bar of conducting material, for example a ceramic or sintered metal powder material. The bar has a cavity forming a pit in which the well of molten metal which is vaporized by the heat of the source is formed. The metal is vaporized continuously and is continuously fed to the cavity in the source in the form of a wire which is unwound from a spool. A description of sources of this type can be found in, “Veredeln von Kunstoff-Oberflächen”, by various authors, Carl Hanser Verlag, Munich, Vienna, 1974, pages 120 et seq., and in U.S. Pat. No. 5,321,792.

One of the most difficult aspects of these sources and this equipment lies in the need to deposit extremely uniform metal coatings on the substrate which is moving above the sources. Special arrangements of the sources which tend to reduce lack of uniformity in the characteristics of the deposited layer as far as possible have been designed for this purpose.

A further critical aspect of vacuum metallizing equipment is the rate of production which can be achieved. This in fact depends on the quantity of metal which can be vaporized per unit time and therefore specifically on the size of the surface being vaporized. In directly heated sources, which have an elongated shape in the direction in which the substrate is fed and a cavity for the molten metal, it is in theory possible to increase the size of the cavity in plan to increase the surface area of evaporating metal. However, as a result of the surface tension in the liquid the molten metal lies in the cavity without fully filling it, but forming a well of circular or elliptical shape. As a consequence the vaporization surface area is less than the surface area of the cavity and cannot be increased. An increase in the number of vaporization sources however encounters a cost limit and a limit to the size of the sources.

One example of a special solution to the arrangement of sources is found in DE-A-402 7034. Here the sources are arranged alongside each other in a direction at right angles to the direction of advance of the strip substrate and are slightly offset with respect to each other in the direction in which the substrate advances.

### OBJECTS AND SUMMARY OF THE INVENTION

The purpose of this invention is to provide vacuum metallizing equipment which makes it possible to increase the surface area of the evaporating liquid and therefore the quantity of metal evaporated while keeping the number of heating systems, that is sources, unchanged, and increasing the uniformity of the coating deposited on the substrate.

A further object of this invention is to provide direct heating sources which make it possible to increase the uniformity of the characteristics of the coating deposited on the substrate by vaporization under vacuum.

These and other objects and advantages which will be clear to those skilled in the art from a reading of the following text are substantially achieved through a vacuum vaporization equipment of the type mentioned above, in which each source is designed and constructed such as to form at least two pools or wells of molten metal material. The two pools are aligned along a main longitudinal direction of extension of each said source. The two pools can be formed by cavities or by surface treated portions of the main upper surface of the source, such as by superficial incisions which alter the wettability of the source surface. The two pools of molten metal can be aligned along the direction in which the substrate is fed, and each of said two pools is fed by a corresponding metal wire delivered from corresponding dispensing means. In this way the surface of the molten metal present in the vaporization source is physically subdivided into two parts. As a consequence more uniform filling of the two cavities is achieved, with the consequent formation of large evaporating surfaces. Although it is possible to envisage the use of a single cavity having a long longitudinal dimension which is fed by two metal wires at each end, in this case the two melting wires would form two adjacent wells of metal in the same cavity, wells which would touch each other in a wholly random way, for example as a result of the fall of drops of molten metal. Contact between the wells of molten metal in the same cavity could give rise to disturbances, and also to splashes of liquid metal onto the substrate, with consequent damage to the substrate. These disadvantages are avoided by physically subdividing the cavities into two, so that each well of metal is isolated from the other. The sources may be arranged parallel to the feed direction along which the substrate to be metallized is fed, or else they may be inclined with respect to said direction.

Subdivision of the evaporating zone into two cavities also has a further advantage: when a drop of metal falls onto the source to make up for the evaporated material it gives rise to disturbances due to the propagation of surface waves which affect an area equal to half the overall vaporizing surface area, with consequent greater uniformity in the deposition of metal onto the substrate.

According to a different aspect, the invention provides a vacuum metallization plant wherein each of the sources is suitable for forming thereon at least two pools of molten metal, which are preferably arranged so as to be approximately aligned in the main longitudinal direction of the source itself, wherein each of said pools of molten metal is fed with a respective metal wire supplied by a respective supplying means, and wherein said sources are arranged with their main longitudinal direction inclined with respect to the direction of feeding of the substrate at an angle other than 0° and 90°.

The inclined arrangement with respect to the direction of feeding of the substrate to be metallized allows an increase in the uniformity of the deposition.

By envisaging the formation of one or more pools on the same source, the surface area of the expanse of molten metal contained in the vaporization source is physically divided into two or more parts. Consequently, it is possible to obtain evaporating surfaces which are particularly extensive and therefore a deposition of large quantities of metal per unit of surface area of the substrate.

The division of the evaporating zone into two cavities also has a further advantage: When a droplet of metal falls onto the source in order to restore the evaporated material, it causes disturbances due to the propagation of the surface ripples which affect a surface area equivalent to half the overall vaporizing surface area, with a consequent greater uniformity in the deposition of the metal on the substrate.

### BRIEF DESCRIPTION OF THE DRAWINGS

The invention will be better understood by following the description and appended drawing, which illustrates a non-restrictive embodiment of the invention. In the drawing

FIG. 1 shows a diagrammatical side view of metallizing equipment,

FIG. 2 shows a detail of a source and the corresponding metal wire feed means in side view,

FIGS. 3 and 4 show a view of a source according to the invention in longitudinal cross section and in plan along IV-IV in FIG. 3;

FIGS. 5 to 7 show diagrammatical views in plan of three possible arrangements of the sources within the equipment;

FIGS. 8, 9 and 10 show plan views of possible configurations of the sources, with the formation of two or three pools of molten metal; and

FIGS. 11 and 12 show schematic plan views of two possible arrangements of the sources inside the plant, in the first case with feeding of two metal wires and formation of two pools of metal and in the second case with feeding of three metal wires and formation of three pools.

### DETAILED DESCRIPTION OF THE PREFERRED EMBODIMENT OF THE INVENTION

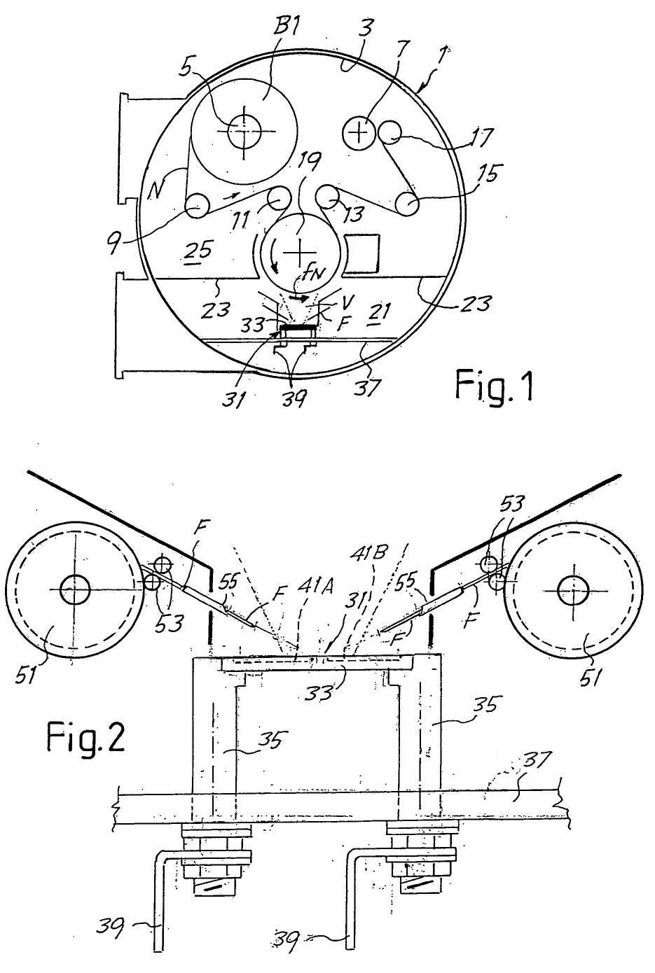

A first embodiment of the invention will now be described, reference being made to FIGS. 1 to 7. FIG. 1 shows the interior of metallizing equipment for vacuum vaporization highly diagrammatically in side view.

This comprises a container 3 in which are located two supports 5 and 7 for the spools of the strip substrate which has to be metallized. A spool B1 of untreated substrate which is fed along a feed path defined by return rollers 9, 11, 13, 15, 17 is mounted on support 5. A second winding spool onto which the substrate is wound after metallization is located on support 7.

A process roller 19 of greater diameter which projects partly within a chamber 21 which is separated by means of a wall 23 from overlying chamber 25 in which supports 5 and 7 for the spools of substrate are located is positioned between roller 11 and roller 13. Chamber 21 is kept under higher vacuum than chamber 25. There are also units in which separating wall 23 and the subdivision into chambers 21 and 25 are not present. In this case the delivery spool, the winding spool, the path of substrate N, process roller 19 and the vaporization sources are all located in the same chamber.

Strip substrate N unwound from spool B1 and passed around process roller 19 is gradually wound so as to form a spool of metallized substrate on support 7. While winding is in progress, in the path around process roller 19 a metal which is vaporized by a set of sources 31 which are located in chamber 21 beneath process roller 19 is deposited onto the surface of strip substrate N which is not in contact with process roller 19. V diagrammatically indicates the vaporized material issuing from sources 31, which are alongside each other in a direction at right angles to the direction FN in which substrate N advances, that is at right angles to the plane of the figure. As a result only one source can be seen in FIG. 1.

The structure of the metallization equipment may vary and what is shown in FIG. 1 is only a diagrammatical example of possible equipment in which the invention may be implemented.

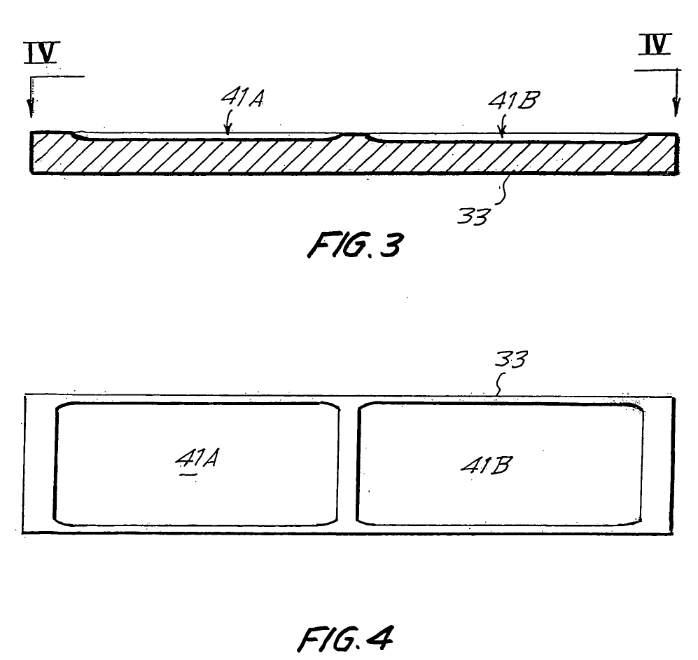

FIG. 2 shows a source 31 of the equipment in FIG. 1 in magnified side view. This source comprises a bar 33 of electrically conducting material which is resistant to high temperatures, typically of the order of 1500° C. Bar 33 is also technically referred to as a boat. This is supported by two columns 35 which are of one piece with a supporting plate 37. Columns 35 are electrically conducting and are connected to two electrical conductors 39 through which a flow of current is caused to pass through boat 33, which as a result of the Joule effect dissipates heat, heating bar or boat 33.

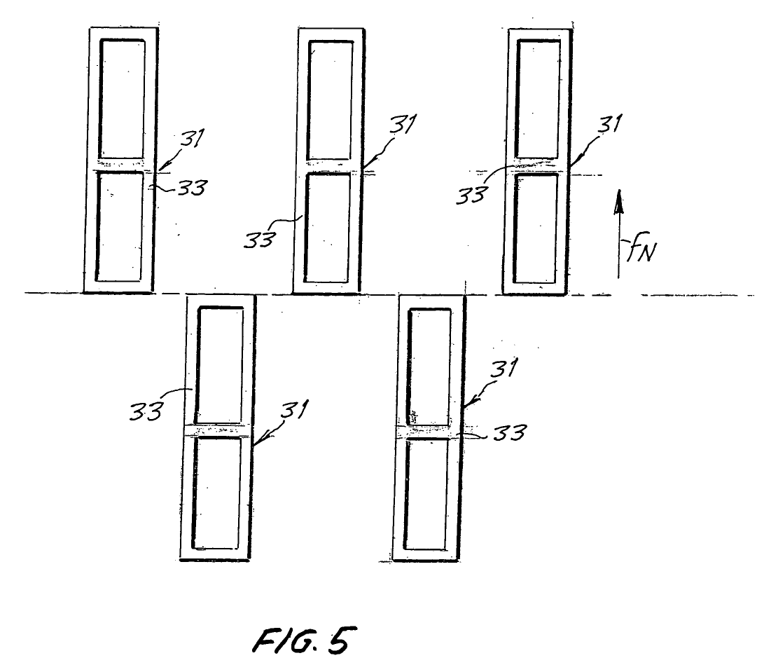

As shown in detail in FIGS. 3 and 4, bar or boat 33 in each source 31 has two shallow cavities 41A, 41B with a flat base and a substantially rectangular shape in plan (see FIG. 4). Wells of liquefied metal which vaporize absorbing the heat generated by the Joule effect of the flow of current through bar or boat 33 form in these cavities 41A, 41B.

In order to maintain the desired level of liquid metal within cavities 41A, 41B and therefore to make up the metal which is delivered by the vaporization source, two separate means for the delivery of metal wire which is designed to be melted by heating by irradiation from part of bar 33 and to fall as drops into cavities 41A and 41B are provided.

The means for the delivery of the metal wire are illustrated diagrammatically in FIG. 2 and may adopt various forms. These delivery means are of a type which are in themselves known and are not described in particular detail here. Diagrammatically in the example illustrated they comprise a reel 51 of metal wire F, a pair of small cylinders 53, at least one of which is motor-driven, for drawing metal wire F and unwinding it from reel 51 and feeding it through a guide tube 55. Metal wire F leaves tube 55 in a zone lying above corresponding cavity 41A or 41B.

The free end of wire F projecting from tube 55 melts gradually as a result of the heat produced by the current flowing in boat/bar 33. The drops of molten metal fall into the corresponding cavity and vaporize. Suitable systems, which are not shown and which are in themselves known, keep the necessary length of wire F projecting from tube 55 and control the gradual unwinding of wire F from reel 51 through small rollers 53.

The existence of two separate cavities on each bar or boat 33 and the feed provided to each of these by means of a separate metal wire has the result that disturbances induced by the drops of molten metal which fall into the wells formed in cavities 41A, 41B are reduced, thus contributing to uniformity of the coating on substrate M.

The various sources 31 may be alongside each other with their corresponding ends aligned along straight lines at right angles to the direction fN in which strip substrate N advances in front of the sources. An arrangement of this type is illustrated in FIG. 6.

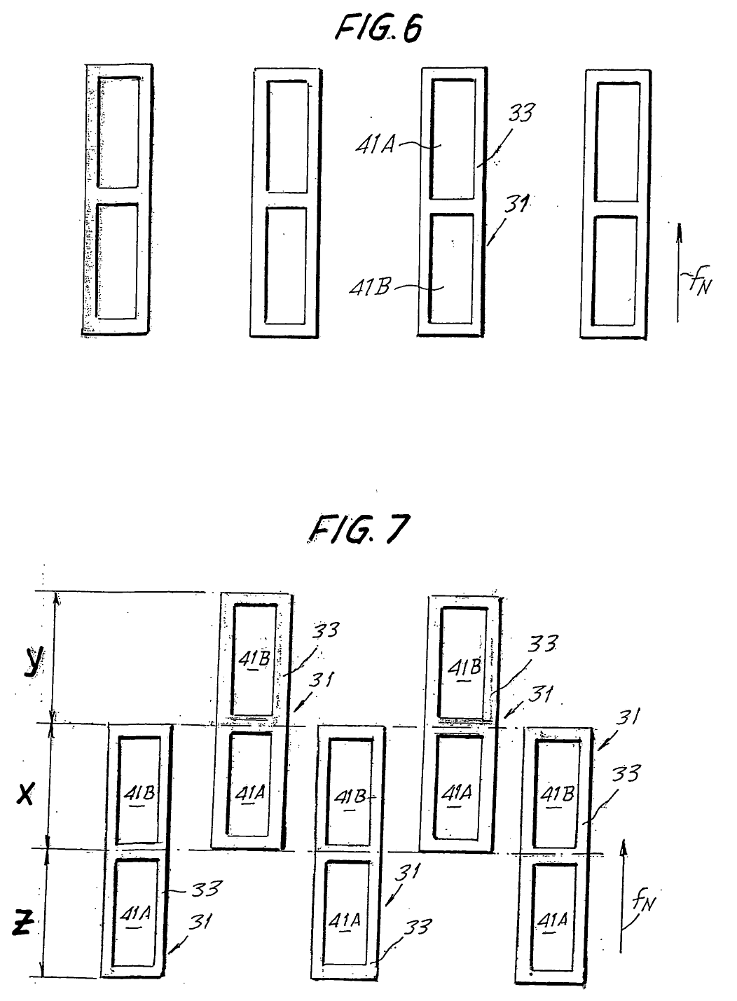

Vice versa, as is in itself known, sources 33 may be offset with respect to each other in the direction in which the strip substrate wound around process roller 19 advances. An arrangement of this type is illustrated for example in FIG. 5, where some sources 31 (here, as in FIG. 6, represented solely by corresponding bars 33) are in an offset arrangement in such a way that the overall zone affected by vaporization of the metal has a width equal to approximately twice the length of bars or boats 33. In this way mutual interference between the clouds of vaporized metal generated by various sources 31 is reduced.

FIG. 7 illustrates an intermediate arrangement in which sources 33 are in an offset arrangement in such a way that all cavities 41B forming one vaporization strip X are in line, while cavities 41A of all the even-numbered sources are aligned in a strip Y and cavities 41A of the odd-numbered sources are aligned in a strip Z. This arrangement is equivalent to the addition of two adjacent rows of auxiliary sources to a row of conventional sources (represented by aligned cavities 41B) in which each comprises a number of sources equal to half the sources in the intermediate row. The two lateral rows (strips Y and Z) help to increase the quantity of metal deposited.

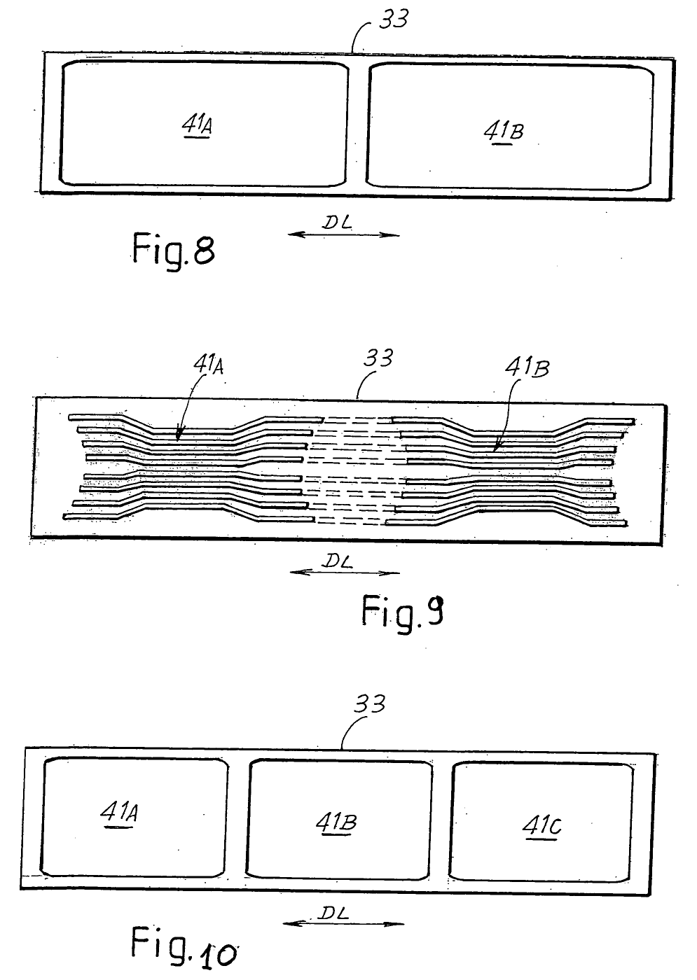

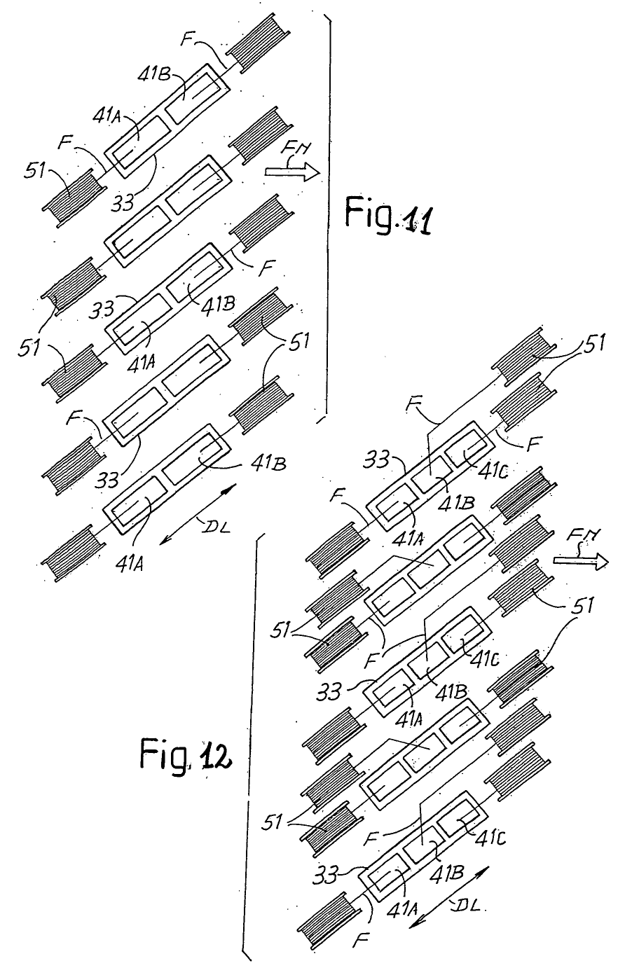

A different embodiment of the invention will now be described with reference to FIGS. 8 to 12. The overall layout of the plant corresponds to that shown in FIGS. 1 and 2. Also for this second embodiment of the invention, the structure of the metallization plant may vary and that which is shown in FIG. 1 is exclusively a schematic example of a possible plant in which the invention may be implemented. According to this embodiment, as will be disclosed in greater detail with reference to FIGS. 11 and 12, the sources are inclined with respect to the direction of feed of the substrate to be metallized. In other words, the main longitudinal direction DL along which each boat extends forms an angle different from 0° and from 90° with the substrate feeding direction FN.

The boats 33 of the metal vapour sources may be variously shaped and designed, as shown by way of example in FIGS. 8, 9 and 10. In FIG. 8 a boat 33 substantially identical to the boat of FIG. 4 is shown. The boat is provided with two depressions or cavities 41A, 41B wherein two separate pools of molten metal are formed. DL indicates the main longitudinal direction along which the boat is developed.

In the example shown in FIG. 9, the bar or boat 33 again has means for forming two pools of molten metal, located at a distance from each other, i.e. physically separated, and aligned in the main longitudinal direction DL of the bar 33. In this case, the zones in which the pools of molten metal are formed each consist of a series of superficial incisions in the bar, having a linear progression and arranged closer together in the central zone. These two arrangements of incisions are again indicated by 41A and 41B and are fed with two metal wires in a similar way to that described above. In reality the incision may not involve the removal of a substantial amount of material such that each incision does not consist of a groove in the material, but for example solely an alteration in the surface characteristics of the material itself, such as for example an alteration of its roughness, with the aim of modifying the surface tension during contact between bar and molten metal, and therefore the wettability of the surface of the source, with a consequent limitation of the zone concerned to the pool of molten metal. The incisions may also be continuous, as shown in broken lines in the figure. This type of incision machining is known per se to persons skilled in the art, but has not been used for the production of this type of sources. The incision lines are typically formed by means of laser machining.

FIG. 10 shows a bar similar to that in FIG. 8, but with three cavities 41A, 41B, 41C which are aligned with each other in the main longitudinal direction DL so as to form three distinct and separate pools of molten metal. In this case also the cavities may be replaced in an equivalent manner by incisions as described with reference to FIG. 4.

As shown in the plan view according to FIG. 11, in which a series of sources of the type illustrated in FIG. 8 can be seen in plan view, the sources 31 are arranged next to each other in an alignment A which is transverse to the direction FN of feeding of the substrate N and in particular perpendicular to the direction of feeding FN of the substrate to be metallized. The various sources 31 are arranged parallel to each other, i.e. with the respective main longitudinal direction DL oriented in the same common direction. Each of the sources 31 is arranged, with respect to the direction FN of feeding of the substrate with an orientation such that they assume a “fish-bone” configuration. Basically the main longitudinal direction DL of each source 31 forms an angle of between for example 15° and 60° with respect to the direction FN and preferably between 20° and 50°. In the example shown, the sources have an inclination of 30° with respect to the direction FN. In this way there is overlapping between the various pools of molten metal in the direction FN of feeding of the substrate to be metallized and this allows a greater uniformity of deposition to be obtained compared to the conventional arrangement of the sources parallel to the direction FN.

Each source is fed with two metal wires supplied on opposite sides of the series of sources aligned with each other in the alignment A. The alignment A is preferably oriented at 90° with respect to the direction FN, but it may be understood that reasonably limited variations of this arrangement are possible.

FIG. 12 shows a plan view similar to the view shown in FIG. 11, with the use of sources comprising three pools of the type illustrated in FIG. 10. Each source is fed by three metal wires supplied by spools arranged alternately on the two sides of the series of sources 31.

It should be understood that the drawing only illustrates an example embodiment of the invention, which may vary in shape and arrangement without however going beyond the scope of the basic concept of the invention.

What we claim is:

1. Vacuum vaporization equipment for metallizing a strip substrate, comprising:
a plurality of vaporization sources which are heated and fed with a metal which is liquefied and vaporized by said sources, each vaporization source having a body extending along a main longitudinal direction;
means for feeding said substrate over said sources along a feed direction,
means for the delivery of metal wire to said sources,
wherein each of said sources is designed to form at least two pools of molten metal on the surface thereof, aligned along said longitudinal direction, and wherein each of said two pools is fed by a corresponding metal wire delivered by corresponding delivery means.

2. Equipment according to claim 1, wherein each of said sources is provided with at least two cavities which are aligned along said longitudinal direction, said cavities defining areas for the formation of said pools of molten metal.

3. Equipment according to claim 2, wherein the two cavities of each source have a rectangular shape in plan which is elongated along said longitudinal direction.

4. Equipment according to claim 1, , wherein the vaporization sources are made of electrically conducting material and are heated by Joule effect as a result of the passage of current.

5. Equipment according to claim 2, wherein the vaporization sources are made of electrically conducting material and are heated by the Joule effect as a result of the passage of current.

6. Equipment according to claim 3, wherein the vaporization sources are made of electrically conducting material and are heated by the Joule effect as a result of the passage of current.

7. Equipment according to claim 1, wherein each of said sources has at least two zones with a respective surface depression so as to form a respective pool of molten metal.

8. Equipment according to claim 7, wherein each of said surface depressions is formed by a plurality of superficial incision lines.

9. Equipment according to claim 1, wherein each of said sources has at least two zones for the formation of pools of liquid metal, each zone being defined in the region of a plurality of superficially processed lines.

10. Equipment according to claim 9, wherein said superficially processed lines are superficial incision lines.

11. Equipment according to claim 7, wherein each of said superficial depressions is formed by a single lowered surface portion of said source.

12. Equipment according to claim 9, wherein said superficially processed lines alter the superficial wettability of the surface of the source in the zones where said at least two pools must be formed.

13. Equipment according to claim 10, wherein said incision lines are laser incision lines.

14. Equipment according to claim 1, wherein said vaporization sources are alongside each other in an alignment transverse to the direction in which the substrate is fed.

15. Equipment according to claim 14, wherein the individual sources are offset with respect to each other along the direction in which the substrate is fed.

16. Equipment according to claim 1, wherein said sources are aligned with their longitudinal direction parallel to said feed direction of said substrate.

17. Source for the vaporization of a metal under vacuum comprising a body with an upper surface, said body being elongated in a longitudinal direction, said upper surface being treated to form at least two pools of molten metal thereon.

18. Source according to claim 17, wherein said upper surface has a pair of cavities alongside each other in the longitudinal direction to form two wells of molten metal.

19. Source for the vaporization of a metal under vacuum comprising an electrically conducting body which is elongated in a longitudinal direction, said body forming a continuous boat or bar with two opposite ends, wherein an upper surface of said boat or bar is treated to form at least two pools of molten metal thereon.

20. Source according to claim 19, wherein a pair of cavities are provided on said surface, arranged alongside each other in said longitudinal direction to form two wells of molten metal.

21. Source according to claim 20, wherein said cavities have a rectangular shape in plan.

22. Source according to claim 20, wherein said cavities have substantially flat bottoms.

23. Source according to claim 19, which is made of electrically conducting material which is heated by the direct passage of current.

24. Source according to claim 19, wherein said upper surface is provided with two zones for forming said two pools of molten metal, each zone being defined in the region of a plurality of superficially processed lines

25. Source according to claim 24, wherein said superficially processed lines are superficial incision lines.

26. Source according to claim 24, wherein said superficially processed lines alter the superficial wettability of the surface of the source in the zones where said at least two pools must be formed

27. Source according to claim 25, wherein said incision lines are laser incision lines.

28. A vacuum vaporization plant for the metallization of a web-like substrate, comprising:
a plurality of vaporization sources supplied with a metal which is liquefied and vaporized by said sources, each source having a body elongated in a respective main longitudinal direction;
means for feeding said substrate above said sources, in a feeding direction, said sources being arranged alongside each other in an alignment substantially perpendicular to said feeding direction;
means for supplying said metal wire to said sources;
means for supporting and heating said sources;
wherein each of said sources is suitable for forming thereon at least two pools of molten metal, wherein each of said pools of molten metal is fed with a respective metal wire supplied by a respective supplying means and wherein said sources are arranged with their main longitudinal direction inclined with respect to the direction of feeding of the substrate at an angle other than 0° and 90°.

29. Plant according to claim 28, wherein said at least two pools of each source are aligned with each other approximately in the main longitudinal direction of the source itself.

30. Plant according to claim 28, wherein the angle between the main longitudinal direction of each source and the direction of feeding of the substrate is such as to position mutually the pools of liquid metal of adjacent sources so that they are at least partially staggered in the direction of said alignment, substantially perpendicular to the direction of feeding of the substrate.

31. Plant according to claim 28, wherein each of said sources has at least two zones with a respective surface depression so as to form a respective pool of molten metal.

32. Plant according to claim 31, wherein each of said surface depressions is formed by a plurality of superficial incision lines.

33. Plant according to claim 28, wherein each of said sources has at least two zones for the formation of pools of liquid metal, each zone being defined in the region of a plurality of superficially processed lines.

34. Plant according to claim 33, wherein said superficially processed lines are superficial incision lines.

35. Plant according to claim 31, wherein each of said superficial depressions is formed by a single lowered surface portion of said source.

36. Plant according to claim 28, wherein the angle between the main longitudinal direction of the sources and the direction of feeding of the substrate is between 15° and 60° and preferably between 20° and 55° and even more preferably between 25° and 45°.
